(19) United States
(12) Patent Application Publication
(10) Pub. No.: US 2024/0042575 A1
(43) Pub. Date: Feb. 8, 2024

(54) WORKPIECE GRINDING METHOD

(71) Applicant: DISCO CORPORATION, Tokyo (JP)

(72) Inventors: Keishi SHINTANI, Tokyo (JP); Yoshikazu SUZUKI, Tokyo (JP)

(21) Appl. No.: 18/359,083

(22) Filed: Jul. 26, 2023

(30) Foreign Application Priority Data
Aug. 4, 2022 (JP) 2022-124547

(51) Int. Cl. B24B 41/047; B24B 1/00; B24B 7/04

(52) U.S. Cl. CPC B24B 41/047; B24B 1/00; B24B 7/04

(57) ABSTRACT

A workpiece grinding method includes a rotary-shaft direction grinding step of grinding a back surface of a workpiece by relatively moving a grinding wheel and a chuck table holding a front surface of the workpiece toward each other along an axis of a rotary shaft of the chuck table, the grinding wheel including a plurality of grinding stones that have outer peripheral surfaces defining a circle of a diameter not greater than a radius of the workpiece, and a radially directed grinding step of grinding the back surface of the workpiece by relatively moving the grinding wheel and the chuck table in a radial direction of the chuck table. The radially directed grinding step includes one of or both an inwardly directed grinding step of relatively moving the grinding wheel and the chuck table, and an outwardly directed grinding step of relatively moving the grinding wheel and the chuck table.

### BACKGROUND OF THE INVENTION

### Field of the Invention

The present invention relates to a workpiece grinding method of grinding a back surface of a workpiece having, on a front surface thereof, a device region and an outer peripheral surplus region surrounding the device region, to form a recessed portion in the back surface, thereby forming a circular thin plate portion and an annular protrusion portion surrounding the circular thin plate portion.

### Description of the Related Art

Along with spreading of systems in package (SiPs) in each of which a plurality of integrated circuits (ICs) are sealed in a single package, for example, there is an outstanding desire for a grinding technology that is capable of thinning disk-shaped workpieces such as wafers each including a plurality of ICs formed thereon, with a good product yield. As one of such grinding technologies for thinning workpieces, a grinding technology called TAIKO (registered trademark in Japan) (hereinafter abbreviated as a “TAIKO process” for the sake of convenience) is known. According to the TAIKO process, a workpiece having, on its front surface, a device region in which devices such as ICs are formed is used, and a circular region on a back surface of the workpiece that corresponds to the device region is ground.

In particular, the grinding of the circular region forms a disk-shaped recessed portion in the back surface and also leaves an annular protrusion portion surrounding an outer peripheral portion of the recessed portion (see, for example, JP 2007-19461A). With the annular protrusion portion remaining, the workpiece can retain higher strength than a workpiece whose entire back surface is evenly thinned. It is therefore possible to suppress warpage of the thinned workpiece, cracking of the thinned workpiece during its transfer, and the like.

When a workpiece is to be ground by the TAIKO process, the front surface of the workpiece is first held under suction with a chuck table. The chuck table is then rotated at a predetermined rotational speed, and an annular grinding wheel is also rotated while a grinding unit which has a spindle with the grinding wheel mounted thereon is moved down toward the chuck table. The grinding wheel has an annular base. On a lower surface of the base, a plurality of grinding stones are arranged at substantially equal intervals along a peripheral direction of the base. An upper surface of the base is fixed on a disk-shaped mount, whereby the grinding wheel is mounted on the spindle via the mount.

To grind the workpiece by the TAIKO process, a grinding wheel of a predetermined diameter is generally selected such that a grinding surface which is defined by a moving path of bottom surfaces of the grinding stones passes right above a center of rotation of the chuck table and that an outer peripheral edge of the grinding surface is located on an inner periphery of the annular protrusion portion. Every time the width (i.e., ring width) of the annular protrusion portion is changed or every time a workpiece having a different diameter is to be ground by the TAIKO process, a grinding wheel having a predetermined diameter corresponding to the ring width or the diameter of the workpiece is hence placed on the mount.

### SUMMARY OF THE INVENTION

However, the replacement of a grinding wheel is generally carried out through manual work by a worker. If the replacement of the grinding wheel is carried out, a problem arises in that the man-hour increases to lower the efficiency of work when grinding a workpiece by the TAIKO process.

The present invention has been made in view of the foregoing problem, and an object thereof is to provide a grinding method that can change the ring width or grind workpieces having different diameters, without replacement of a grinding wheel when grinding the workpiece by the TAIKO process.

In accordance with an aspect of the present invention, there is provided a workpiece grinding method of grinding a back surface of a workpiece having, on a front surface thereof, a device region and an outer peripheral surplus region surrounding the device region, to form a recessed portion in the back surface, thereby forming a circular thin plate portion and an annular protrusion portion surrounding the circular thin plate portion. The grinding method includes a holding step of holding the front surface of the workpiece with a holding surface of a chuck table that is rotatable about an axis of a rotary shaft, a rotary-shaft direction grinding step of grinding the back surface of the workpiece by relatively moving a grinding unit and the chuck table toward each other along the axis of the rotary shaft of the chuck table, the grinding unit including a spindle having a distal end portion to which a grinding wheel is mounted, the grinding wheel including an annular base and a plurality of grinding stones that are arranged in an annular pattern on one surface of the base and that have outer peripheral surfaces defining a circle of a diameter not greater than a radius of the workpiece, and a radially directed grinding step of grinding the back surface of the workpiece by relatively moving the grinding unit and the chuck table in a radial direction of the chuck table, the radial direction being orthogonal to the axis. The radially directed grinding step includes one of or both an inwardly directed grinding step of grinding the workpiece while relatively moving the grinding unit and the chuck table from a position where a moving path of bottom surfaces of the grinding stones that is formed together with rotation of the spindle and the axis of the chuck table do not overlap each other to a position where the moving path and the axis of the chuck table overlap each other, and an outwardly directed grinding step of grinding the workpiece while relatively moving the grinding unit and the chuck table from the position where the moving path and the axis overlap each other to the position where the moving path and the axis do not overlap each other.

Preferably, in the radially directed grinding step, the inwardly directed grinding step and the outwardly directed grinding step may alternately be repeated to grind the workpiece.

Preferably, the rotary-shaft direction grinding step and the radially directed grinding step may concurrently be performed to grind the workpiece, and the radially directed grinding step may include both the inwardly directed grinding step and the outwardly directed grinding step.

Preferably, in the holding step, the workpiece may be held with the holding surface having a planarity of smaller than 10 μm in terms of roughness, and in the rotary-shaft direction grinding step and the radially directed grinding step, the workpiece held with the holding surface having the planarity may be ground.

Preferably, in the rotary-shaft direction grinding step and the radially directed grinding step, the workpiece may be ground with an axis of the spindle of the grinding unit arranged in non-parallel with the axis of the chuck table.

The workpiece grinding method according to the aspect of the present invention includes the rotary-shaft direction grinding step of relatively moving the grinding unit and the chuck table toward each other along the axis of the rotary shaft of the chuck table, and the radially directed grinding step of relatively moving the grinding unit and the chuck table in the radial direction of the chuck table. The radially directed grinding step includes one of or both the inwardly directed grinding step and the outwardly directed grinding step. In the inwardly directed grinding step, the grinding unit and the chuck table are relatively moved from the position where the moving path of the bottom surfaces of the grinding stones and the axis of the rotary shaft of the chuck table do not overlap each other to the position where the moving path and the axis overlap each other. In the outwardly directed grinding step, on the other hand, the grinding unit and the chuck table are relatively moved from the position where the moving path and the axis overlap each other to the position where the moving path and the axis do not overlap each other. Owing to the grinding of the workpiece while relatively moving the grinding unit and the chuck table in the radial direction of the chuck table in one of or both the inwardly directed grinding step and the outwardly directed grinding step as described above, the grinding method according to the aspect of the present invention can change the ring width or grind another workpiece having a different diameter, without replacement of a grinding wheel.

The above and other objects, features and advantages of the present invention and the manner of realizing them will become more apparent, and the invention itself will best be understood from a study of the following description and appended claims with reference to the attached drawings showing some preferred embodiments of the invention.

### BRIEF DESCRIPTION OF THE DRAWINGS

FIG. 1 is a flow diagram of a workpiece grinding method according to a first embodiment of the present invention;

FIG. 2 is a perspective view illustrating the workpiece and a protective member which is to be bonded to the workpiece;

FIG. 3A is a fragmentary cross-sectional side view illustrating a holding step in the grinding method according to the first embodiment;

FIG. 3B is a perspective view illustrating the holding step;

FIG. 4 is a cross-sectional view of a chuck table that is generally used in the TAIKO process;

FIG. 5 is a partial cross-sectional side view illustrating a rotary-shaft direction grinding step in the grinding method according to the first embodiment;

FIG. 6A is a partial cross-sectional side view illustrating an inwardly directed grinding step in the grinding method according to the first embodiment;

FIG. 6B is a perspective view illustrating the inwardly directed grinding step;

FIG. 7 is a cross-sectional side view of the workpiece that has undergone the grinding by the grinding method according to the first embodiment;

FIG. 8 is a flow diagram of a workpiece grinding method according to a second embodiment of the present invention;

FIG. 9 is a partial cross-sectional side view illustrating a rotary-shaft direction grinding step in the grinding method according to the second embodiment;

FIG. 10A is a partial cross-sectional side view illustrating an outwardly directed grinding step in the grinding method according to the second embodiment;

FIG. 10B is a fragmentary perspective view illustrating the outwardly directed grinding step;

FIG. 11 is a flow diagram of a workpiece grinding method according to a third embodiment of the present invention;

FIG. 12 is a partial cross-sectional side view illustrating an inwardly directed grinding step and an outwardly directed grinding step in the grinding method according to the third embodiment;

FIG. 13 is a flow diagram of a workpiece grinding method according to a fourth embodiment of the present invention;

FIG. 14 is a partial cross-sectional side view illustrating a rotary-shaft direction grinding step and a radially directed grinding step in the grinding method according to the fourth embodiment;

FIG. 15A is a partial cross-sectional side view illustrating a rotary-shaft direction grinding step and a radially directed grinding step in a workpiece grinding method according to a fifth embodiment of the present invention; and

FIG. 15B is a top view illustrating the rotary-shaft direction grinding step and the radially directed grinding step in the grinding method according to the fifth embodiment.

### DETAILED DESCRIPTION OF THE PREFERRED EMBODIMENTS

With reference to the attached drawings, some embodiments of the present invention will be described below.

### First Embodiment

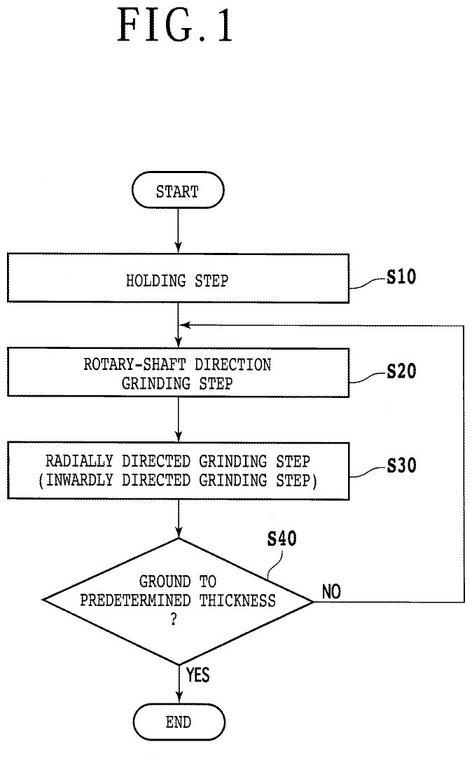

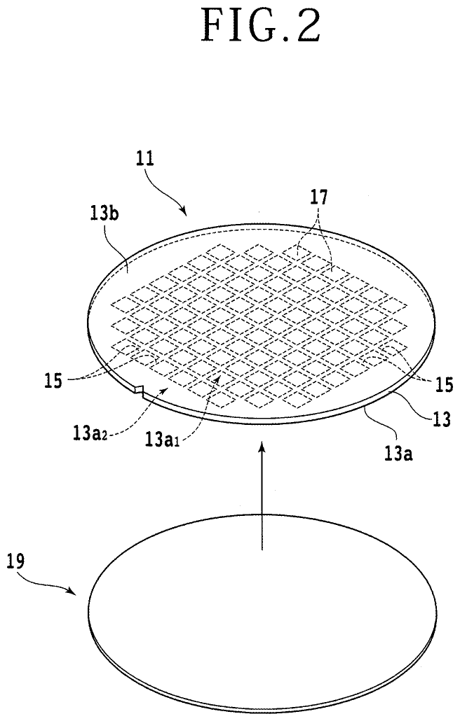

FIG. 1 is a flow diagram of a method of grinding a workpiece 11 (see FIG. 2, etc.) in a first embodiment. In the present embodiment, the workpiece 11 is ground according to individual steps illustrated in FIG. 1. Now, with reference to FIG. 2, the workpiece 11 will first be described. FIG. 2 is a perspective view illustrating the workpiece 11 and a protective member 19 which is to be bonded to a front surface 13a of a disk-shaped wafer 13 as the workpiece 11.

As illustrated in FIG. 2, the workpiece 11 has the disk-shaped wafer 13 which is formed of single-crystal silicon. On the front surface 13a of the wafer 13, a plurality of division lines (streets) 15 are set in a grid pattern. In respective rectangular regions defined by the division lines 15, devices 17 such as ICs are formed. A circular region on the front surface 13a where the devices 17 are formed is called a “device region 13a₁.” It is to be noted that no limitations are imposed on the type, number, shape, structure, size, arrangement, and the like of the devices 17 on the workpiece 11.

A region on the front surface 13a which surrounds a periphery of the device region 13a₁ is called “an outer peripheral surplus region 13a₂.” It is to be noted that the front surface 13a of the wafer 13 may be rephrased as a front surface of the workpiece 11, and that a back surface 13b of the wafer 13 may be rephrased as a back surface of the workpiece 11. In some cases, a function layer (not illustrated) that has a metal interconnection layer, an interlayer dielectric film, and the like may be disposed such that it covers the front surface 13a and devices 17 on the wafer 13.

When the workpiece 11 is ground, a circular region on the back surface 13b that corresponds to the device region 13a₁ is ground, thereby thinning part of the wafer 13. It is to be noted that this circular region has a diameter smaller than the outer diameter of the wafer 13 and is concentric with the wafer 13. Before the wafer 13 is ground, the protective member 19 which is made of resin and which has substantially the same diameter as the wafer 13 is bonded to the front surface 13a.

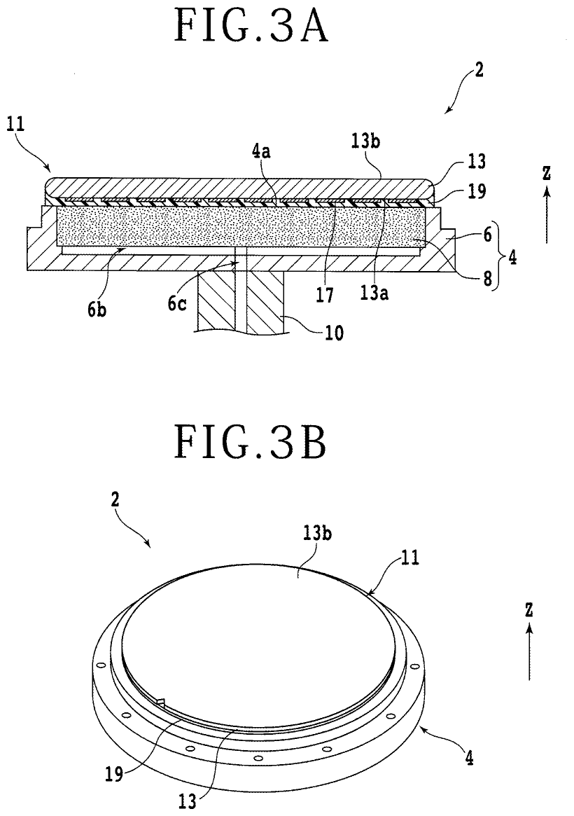

The protective member 19 is, for example, a circular tape having a base material layer and a adhesive layer, and the adhesive layer of the tape is bonded to the front surface 13a. Owing to the protective member 19 bonded to the front surface 13a, it is possible to mitigate impacts to the devices 17 during grinding. It is to be noted that the protective member 19 may have only the base material layer without the adhesive layer. If this is the case, the protective member 19 is thermocompression-bonded to the front surface 13a. The thermocompression bonding of the protective member 19 to the front surface 13a can prevent the adhesive layer from remaining in part on the front surface 13a when the protective member 19 is peeled off from the front surface 13a. After the protective member 19 has been bonded to the front surface 13a, the front surface 13a of the wafer 13 is held under suction with a chuck table 4 of a grinding machine 2 (see FIG. 3A) (holding step S10).

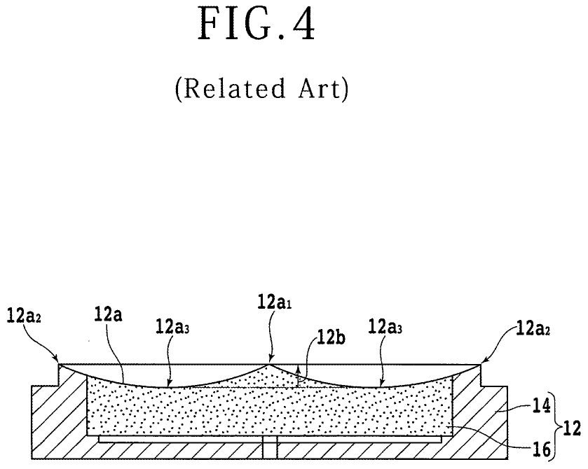

FIG. 3A is a fragmentary cross-sectional side view illustrating the holding step S10, and FIG. 3B is a perspective view illustrating the holding step S10. A Z-axis direction illustrated in FIGS. 3A and 3B is parallel to a height direction of the grinding machine 2 (that is, a vertical direction). The chuck table 4 has a disk-shaped frame body 6 formed of non-porous ceramics. On an upper surface of the frame body 6, a circular recessed portion is formed. In this recessed portion, a disk-shaped porous plate 8 formed of porous ceramics is fixed. The upper surface of the frame body 6 and an upper surface of the porous plate 8 are substantially flush with each other, thereby forming a substantially planar holding surface 4a. The holding surface 4a has higher planarity than a holding surface 12a of a chuck table 12 (see FIG. 4) that is generally used in the TAIKO process.

FIG. 4 is a cross-sectional view of the chuck table 12 that is generally used in the TAIKO process. FIG. 4 illustrates a cross-section of the chuck table 12 in a plane that passes through a central portion 12a₁ in a radial direction of the chuck table 12 and that is orthogonal to a bottom surface of the chuck table 12. The chuck table 12 also has a frame body 14 and a porous plate 16. An upper surface of the frame body 14 and an upper surface of the porous plate 16 are substantially flush with each other, thereby forming the holding surface 12a with which the workpiece 11 is held under suction.

On the holding surface 12a, however, the central portion 12a₁ and an outer peripheral portion 12a2 in the radial direction of the chuck table 12 are upwardly protruding compared with other regions, so that the holding surface 12a as viewed in cross-section has what is called a double recessed shape. The central portion 12a₁ and the outer peripheral portion 12a₂ are protruding by a predetermined height 12b of 10 μm or greater but 30 μm or smaller in a thickness direction of the chuck table 12 from most depressed bottom portions 12a3.

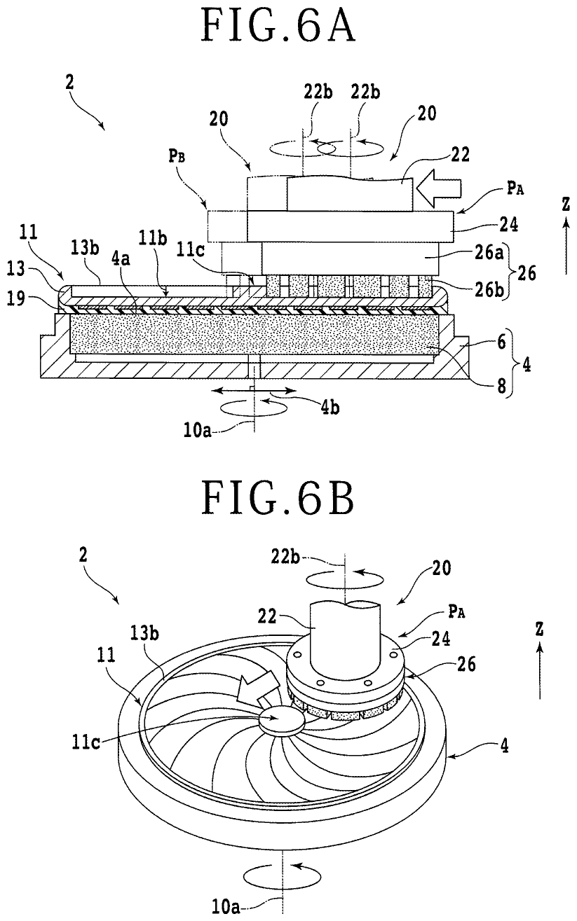

On the other hand, the holding surface 4a of the chuck table 4 in the present embodiment as illustrated in FIG. 3A is substantially planar, and its roughness are smaller than 10 μm. It is one of characteristic features of the present invention that the workpiece 11 is held under suction with the substantially planar holding surface 4a in the TAIKO process. The roughness of the holding surface 4a are assessed, for example, on the basis of an arithmetical mean roughness (Ra) of a profile in a cross-section of the chuck table 4 in a plane that passes through a center in a radial direction 4b (see FIG. 6A) of the chuck table 4 and that is orthogonal to the bottom surface of the chuck table 12. The arithmetical mean roughness (Ra) is specified, for example, in the Japanese Industrial Standards (JIS) B 0601:2013. The Ra of the holding surface 4a in the present embodiment is 2.99 μm (that is, smaller than 10 μm).

As illustrated in FIG. 3A, in a bottom part of the recessed portion of the frame body 6, flow paths 6b are radially formed, and a cylindrical flow channel 6c is also formed to extend through a central portion in a radial direction of the frame body 6. To the flow channel 6c, a suction source (not illustrated) such as a vacuum pump is connected via a valve (not illustrated) such as a solenoid valve. When the valve is brought into an open position with the suction source kept in operation, a negative pressure is transmitted to the holding surface 4a, so that the workpiece 11 is held under suction with the holding surface 4a. More specifically, the protective member 19 bonded to the front surface 13a of the wafer 13 is held under suction on the holding surface 4a with the back surface 13b of the wafer 13 being exposed. On a lower surface of the frame body 6, a cylindrical rotary shaft (rotary shaft) 10 is fixed. The rotary shaft 10 extends in a length direction which is substantially parallel to the Z-axis direction and which is substantially orthogonal to the holding surface 4a.

In a vicinity of a lower end portion of the rotary shaft 10, a driven pulley (not illustrated) is fixed. Further, below the chuck table 4, a rotary drive source (not illustrated) such as a motor is disposed. On an output shaft of the rotary drive source, a driving pulley (not illustrated) is fixed. A toothed endless belt (not illustrated) is wrapped on the driving pulley and the driven pulley. When power of the rotary drive source is transmitted to the rotary shaft 10, the chuck table 4 rotates about an axis of the rotary shaft 10.

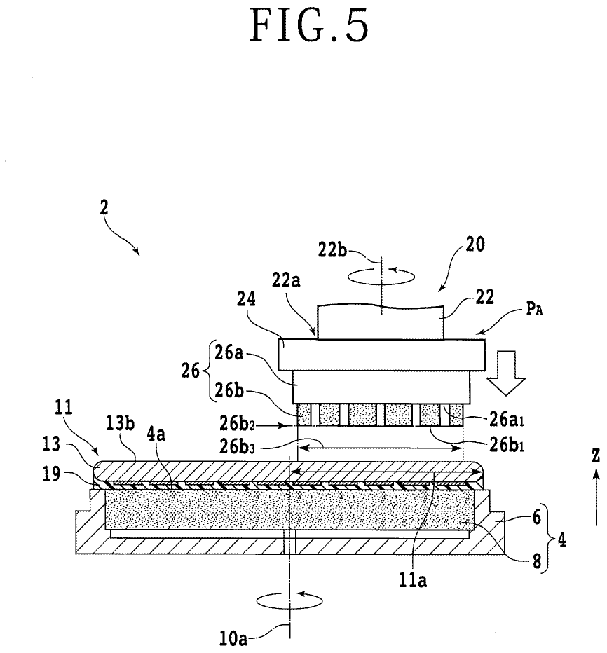

After the holding step S10, the back surface 13b of the wafer 13 held under suction with the holding surface 4a is ground by a grinding unit 20 (see FIG. 5). FIG. 5 is a partial cross-sectional side view illustrating a rotary-shaft direction grinding step S20 in the present embodiment. The grinding unit 20 has a cylindrical spindle housing (not illustrated). To the spindle housing, a ball screw type Z-axis direction moving mechanism (not illustrated) is connected, and the grinding unit 20 is thus moved along the Z-axis direction by the Z-axis direction moving mechanism. Inside the spindle housing, a portion of a cylindrical spindle 22 is rotatably accommodated.

Longitudinal directions of the spindle housing and the spindle 22 are arranged along the Z-axis direction. In addition to the spindle 22, FIG. 5 also illustrates an axis 22b that extends through a center of rotation of the spindle 22 (for example, a figure center in a cross-section orthogonal to the longitudinal direction of the spindle 22) and that is substantially parallel to the Z-axis direction. On an upper portion of the spindle 22, a rotary drive source (not illustrated) such as a motor is disposed. The spindle 22 has a lower end portion (distal end portion) 22a downwardly projecting beyond a lower end of the spindle housing. On the lower end portion 22a of the spindle 22, a disk-shaped mount 24 of a diameter smaller than that of the holding surface 4a is fixed.

On a lower surface of the mount 24, an annular grinding wheel 26 is mounted. In other words, the grinding wheel 26 is mounted on the lower end portion 22a of the spindle 22 via the mount 24. The grinding wheel 26 has an annular wheel base (base) 26a formed of such metal as an aluminum alloy. On a lower surface (one surface) 26a₁ of the wheel base 26a, a plurality of grinding stones 26b are arranged at substantially equal intervals along a peripheral direction of the wheel base 26a.

Each grinding stone 26b has abrasive grains formed of cubic boron nitride (cBN), diamond, or the like, and a bonding material such as a vitrified bond or a resin bond that fixes the abrasive grains. An annular region which is defined by a moving path of bottom surfaces 26b1 of the grinding stones 26b when the spindle 22 is rotated serves as a grinding surface 26b2 for grinding the back surface 13b of the wafer 13. It is to be noted that, in FIG. 5, a position of the grinding surface 26b₂ in the Z-axis direction is illustrated. The grinding surface 26b₂ has a diameter (outer diameter) corresponding to a diameter 26b₃ of a circle defined by outer peripheral side surfaces of the grinding stones 26b in a plane orthogonal to the axis 22b. The diameter 26b₃ of the grinding stones 26b is not greater than a radius 11a of the workpiece 11.

In the lower surface 26a₁ of the wheel base 26a, a plurality of openings (not illustrated) through which grinding water such as pure water can be supplied to the grinding stones 26b, etc., are formed at substantially equal intervals along the peripheral direction of the wheel base 26a on a radially inner side of the grinding stones 26b. During grinding, the grinding water is used for cooling and removal of grinding debris. The grinding unit 20 and the chuck table 4 are relatively moved toward each other along an axis 10a of the rotary shaft 10 of the chuck table 4 by the Z-axis direction moving mechanism, so that the back surface 13b of the wafer 13 is ground (rotary-shaft direction grinding step S20).

In FIG. 5 and subsequent figures, the rotary shaft of the chuck table 4 is simplified and illustrated as the axis 10a. It is to be noted that the axis 10a is a straight line which passes through a center of rotation of the rotary shaft 10 (for example, a figure center in a cross-section orthogonal to a longitudinal direction of the rotary shaft 10) and which is substantially parallel to the Z-axis direction. In the present embodiment, the grinding wheel 26 is rotated at 4,000 rpm, the chuck table 4 is rotated at 300 rpm, and further, the grinding unit 20 is moved down (that is, is fed for grinding) at 0.6 μm/s along the Z-axis direction. It is to be noted that the flow rate of the grinding water is set, for example, at 4.0 L/min.

As mentioned above, the diameter 26b₃ of the grinding stones 26b is not greater than the radius 11a of the workpiece 11. Further, when the grinding unit 20 is fed for grinding, the position of the chuck table 4 is adjusted such that, as illustrated in FIG. 5, the grinding surface 26b₂ of the grinding wheel 26 is located at a position P_{A} where the grinding surface 26b₂ of the grinding wheel 26 does not overlap the axis 10a of the chuck table 4. FIG. 6A is a partial cross-sectional side view illustrating an inwardly directed grinding step. As illustrated in FIG. 6A, a cylindrical protrusion portion 11c (that is, an unground region) is thus formed at a central portion on the back surface 13b when the grinding surface 26b₂ is fed for grinding from the back surface 13b to a predetermined target depth 11b.

After the protrusion portion 11c has been formed, the grinding feed of the grinding unit 20 is stopped. The grinding unit 20 and the chuck table 4 are then relatively moved in the radial direction 4b of the chuck table 4, so that the protrusion portion 11c on the side of the back surface 13b is ground and removed (radially directed grinding step S30).

As illustrated in FIG. 6A, the radial direction 4b of the chuck table 4 is orthogonal to the axis 10a of the rotary shaft 10. It is to be noted that the radial direction 4b shown in FIG. 6A is substantially parallel to an X-axis direction (not illustrated) orthogonal to the Z-axis direction in the grinding machine 2. In the radially directed grinding step S30, the grinding wheel 26 is moved inward in the radial direction 4b, for example, by moving the chuck table 4 outward in the radial direction 4b shown in FIG. 6A while both the chuck table 4 and the grinding wheel 26 are rotated.

As a consequence, the protrusion portion 11c is removed (that is, the back surface 13b of the wafer 13 is ground) by the outer peripheral side surfaces of the grinding stones 26b while the grinding wheel 26 is moved toward a center of the holding surface 4a, i.e., is moved from the above-mentioned position P_{A} to a position P_{B} where the grinding surface 26b₂ and the axis 10a overlap each other (inwardly directed grinding step). FIG. 6B is a perspective view illustrating the inwardly directed grinding step. The moving speed of the grinding wheel 26 when the grinding wheel 26 is moved from the position P_{A} to the position P_{B} is set, for example, at 1.0 μm/s.

In the present embodiment, the rotary-shaft direction grinding step S20 and the radially directed grinding step (inwardly directed grinding step) S30 are sequentially performed to grind the wafer 13 to a predetermined thickness (“YES” in S40), and the grinding is then ended (see FIG. 1). When the amount of the first grinding feed is shallower than the predetermined target depth 11b (“NO” in S40), on the other hand, the rotary-shaft direction grinding step S20 and the radially directed grinding step (inwardly directed grinding step) S30 are repeated (see FIG. 1).

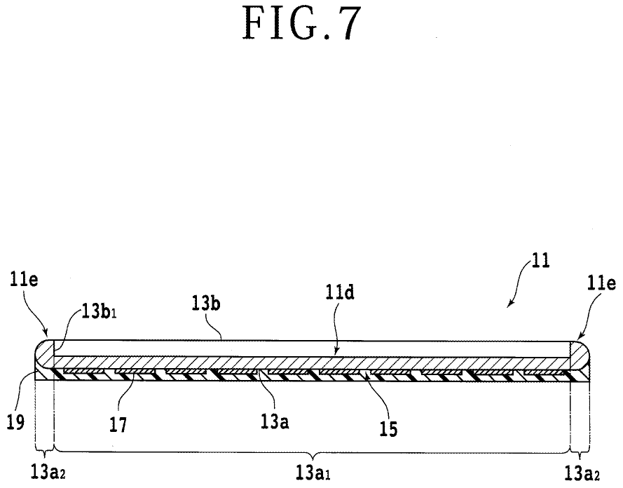

FIG. 7 is a cross-sectional side view of the workpiece 11 that has undergone the grinding. With a recessed portion 13b₁ formed on the back surface 13b, a circular thin plate portion 11d which includes the device region 13a₁ and an annular protrusion portion 11e which surrounds an outer peripheral portion of the circular thin plate portion 11d are formed in the workpiece 11.

In the present embodiment, the grinding unit 20 and the chuck table 4 are relatively moved in the radial direction of the chuck table 4 in the inwardly directed grinding step. Hence, although the diameter 26b₃ of the grinding stones 26b is not greater than the radius 11a of the workpiece 11, the grinding of the workpiece 11 can be performed without replacement of the grinding wheel 26. It is to be noted, with the grinding method according to the present embodiment, it is possible to change the ring width of the annular protrusion portion 11e or to grind another workpiece 11 having a different diameter from that of the above-described workpiece 11, by changing the position of the grinding wheel 26 relative to the above-described workpiece 11 in the rotary-shaft direction grinding step S20.

### Second Embodiment

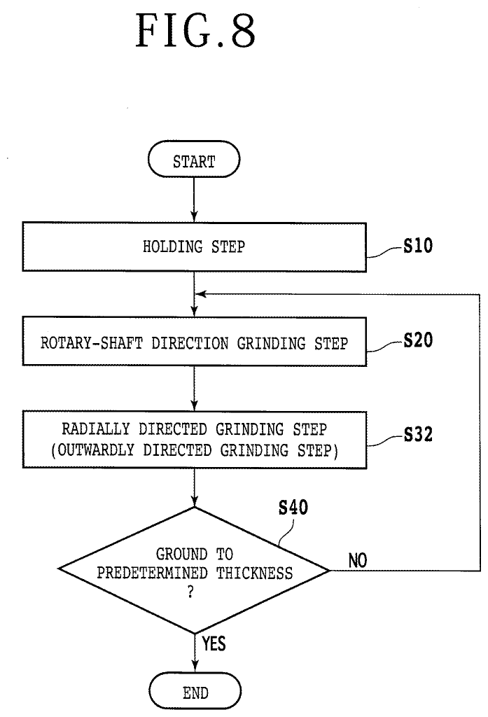

With reference to FIGS. 8, 9, 10A, and 10B, a second embodiment will next be described. FIG. 8 is a flow diagram of a method of grinding the workpiece 11 in the second embodiment. In the second embodiment, a rotary-shaft direction grinding step S20 is also performed after the holding step S10.

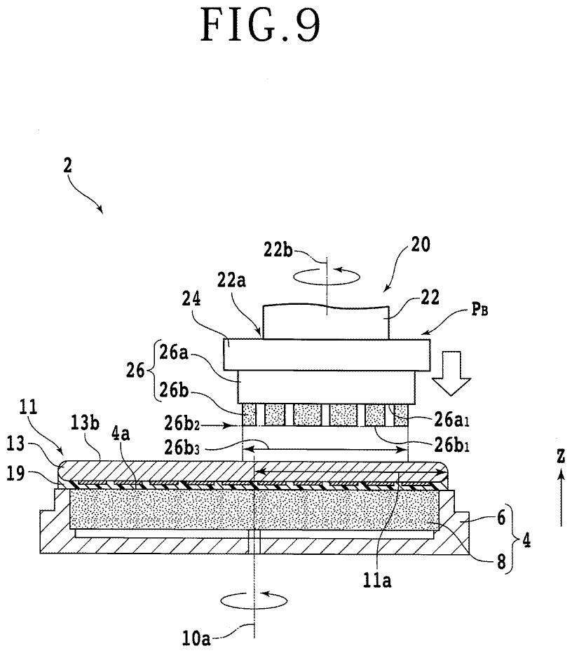

FIG. 9 is a partial cross-sectional side view illustrating the rotary-shaft direction grinding step S20 in the second embodiment. In the rotary-shaft direction grinding step S20 in the present embodiment, however, the grinding unit 20 is fed for grinding after the position of the chuck table 4 is adjusted such that, as illustrated in FIG. 9, the grinding surface 26b₂ of the grinding wheel 26 is located at the position P_{B} where the grinding surface 26b₂ overlaps the axis 10a of the chuck table 4.

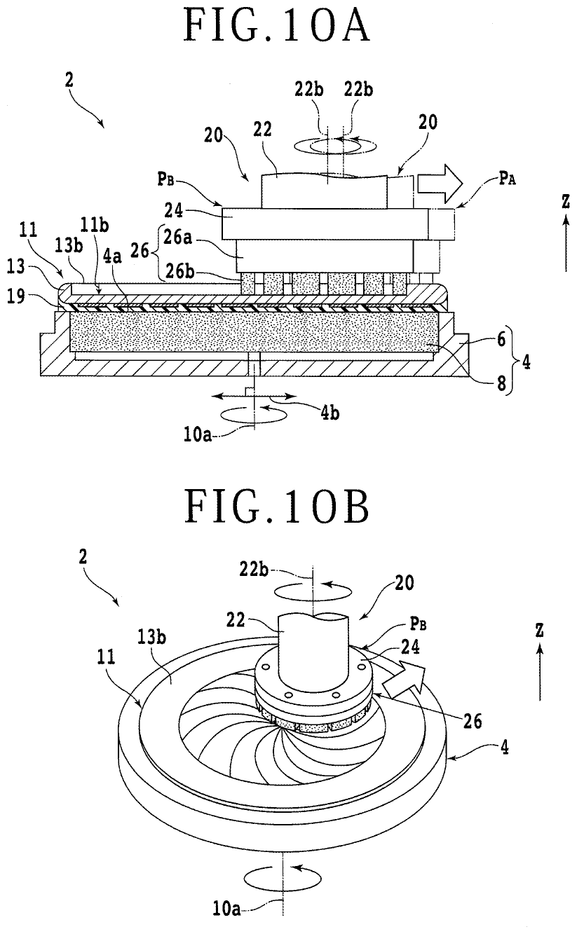

In the present embodiment, the grinding wheel 26 is rotated at 4,000 rpm, the chuck table 4 is rotated at 300 rpm, and further, the grinding unit 20 is fed for grinding at 0.6 μm/s along the Z-axis direction. It is to be noted that the flow rate of the grinding water is set, for example, at 4.0 L/min. FIG. 10A is a partial cross-sectional side view illustrating an outwardly directed grinding step. After the grinding surface 26b₂ (see FIG. 9) has been fed for grinding from the back surface 13b to the predetermined depth 11b as illustrated in FIG. 10A, the grinding feed of the grinding unit 20 is stopped. After the rotary-shaft direction grinding step S20, a radially directed grinding step S32 is then performed.

In the radially directed grinding step S32, the back surface 13b of the wafer 13 is ground while the grinding wheel 26 is relatively moved outwardly of the holding surface 4a from the above-mentioned position P_{B} to the position P_{A} where the grinding surface 26b₂ and the axis 10a do not overlap each other (outwardly directed grinding step). While both the chuck table 4 and the grinding wheel 26 are rotated, the chuck table 4, for example, is moved inward in the radial direction 4b in FIG. 10A, so that the grinding wheel 26 is moved outward in the radial direction 4b in FIG. 10A.

The moving rate of the grinding wheel 26 when the grinding wheel 26 is moved from the position P B to the position P_{A} is set, for example, at 1.0 μm/s. FIG. 10B is a fragmentary perspective view illustrating the outwardly directed grinding step. In the present embodiment, the grinding of the workpiece 11 can be also performed without replacement of the grinding wheel 26. Further, with the grinding method according to the present embodiment, it is also possible to change the ring width of the annular protrusion portion 11e (see FIG. 7) or to grind another workpiece 11 having a different diameter from that of the above-described workpiece 11.

### Third Embodiment

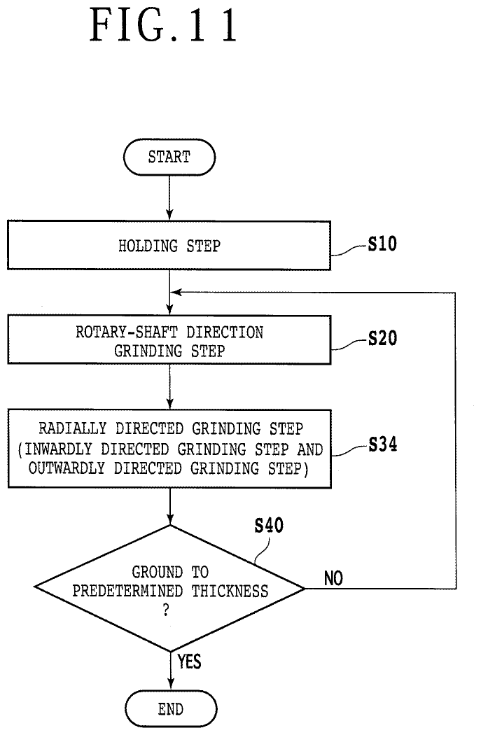

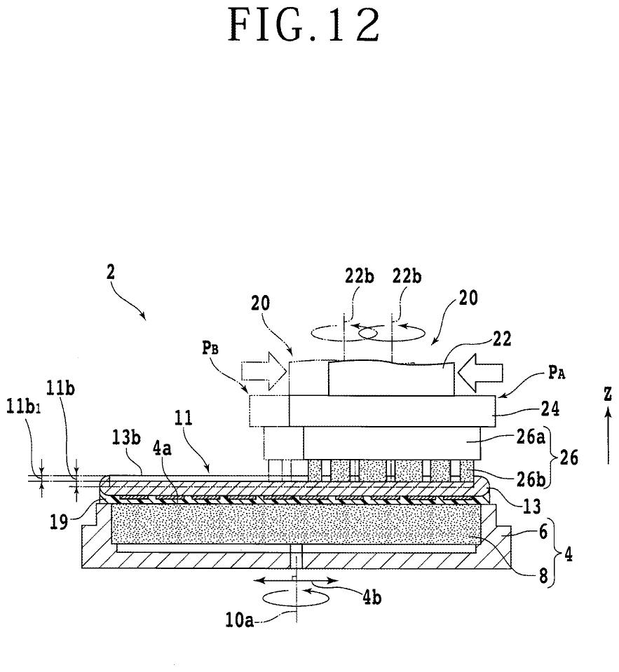

With reference to FIGS. 11 and 12, a third embodiment will next be described. FIG. 11 is a flow diagram of a method of grinding the workpiece 11 in the third embodiment. FIG. 12 is a partial cross-sectional side view illustrating an inwardly directed grinding step and an outwardly directed grinding step in the radially directed grinding step S34. In the third embodiment, a rotary-shaft direction grinding step S20 is also performed after the holding step S10. In the rotary-shaft direction grinding step S20 in the present embodiment, however, the grinding unit 20 is fed for grinding after the position of the chuck table 4 is adjusted such that, as illustrated in FIG. 12, the grinding unit 20 is located between the position P_{A} and the position P_{B}.

After the grinding surface 26b₂ (see FIG. 9) has been fed for grinding to a depth 11b₁ shallower than the predetermined depth 11b, the grinding feed of the grinding unit 20 is stopped. In a radially directed grinding step S34 that follows, the grinding unit 20 is relatively moved along the radial direction 4b of the chuck table 4. For example, the grinding unit 20 is first relatively moved inward in the radial direction 4b in FIG. 12 to the position P_{B} (inwardly directed grinding step).

Next, the grinding unit 20 is relatively moved outward in the radial direction 4b in FIG. 12 from the position P_{B} to the position P_{A} (outwardly directed grinding step).

It is to be noted that, in the radially directed grinding step S34, the inwardly directed grinding step and the outwardly directed grinding step may each be performed once or a plurality of times. If performed a plurality of times, the inwardly directed grinding step and the outwardly directed grinding step are alternately repeated. If alternately repeated, either the inwardly directed grinding step or the outwardly directed grinding step may be performed first. As described above, the circular thin plate portion 11d and the annular protrusion portion 11e are formed in the workpiece 11 by grinding the back surface 13b of the wafer 13 to the predetermined target depth 11b (that is, until “YES” in S40).

In the present embodiment, the grinding of the workpiece 11 can be also performed without replacement of the grinding wheel 26. Further, with the grinding method according to the present embodiment, it is also possible to change the ring width of the annular protrusion portion 11e (see FIG. 7) or to grind another workpiece 11 having a different diameter from that of the above-described workpiece 11. It is to be noted that the circular thin plate portion 11d and the annular protrusion portion 11e may be formed by performing the radially directed grinding step S34 after the grinding surface 26b₂ (see FIG. 9) is fed for grinding to the predetermined target depth 11b in the first rotary-shaft grinding step S20.

### Fourth Embodiment

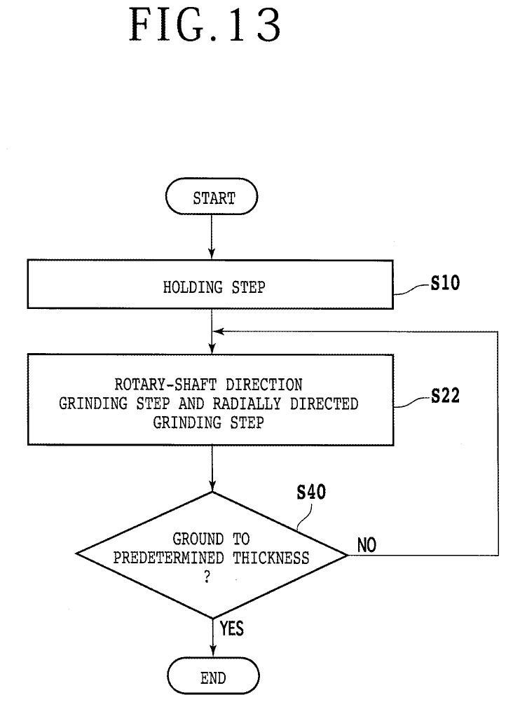

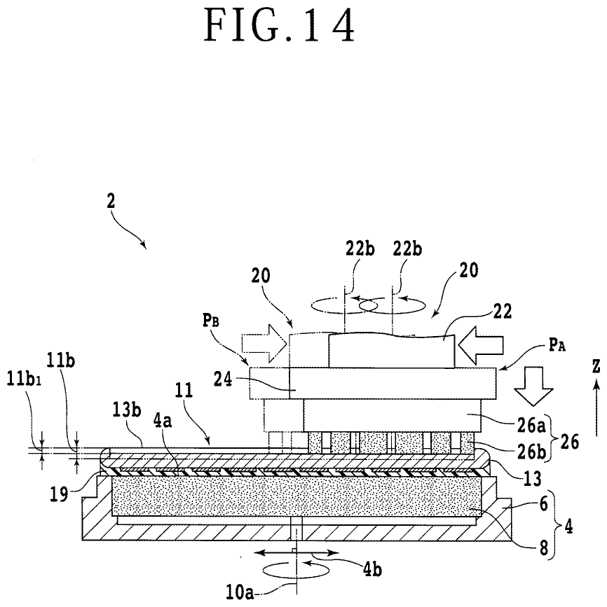

With reference to FIGS. 13 and 14, a fourth embodiment will next be described. FIG. 13 is a flow diagram of a method of grinding the workpiece 11 in the fourth embodiment. FIG. 14 is a partial cross-sectional side view illustrating a rotary-shaft direction grinding step and radially directed grinding step S22. In the fourth embodiment, the rotary-shaft direction grinding step and radially directed grinding step S22 is performed after the holding step S10. In other words, after the holding step S10, the rotary-shaft direction grinding step and the radially directed grinding step are concurrently performed to grind the back surface 13b of the wafer 13. Described specifically, both an inwardly directed grinding step and an outwardly directed grinding step are performed by reciprocating the chuck table 4 along the radial direction 4b in FIG. 14 while feeding the grinding unit 20 for grinding by the Z-axis direction moving mechanism.

It is to be noted that, in the radially directed grinding step, the inwardly directed grinding step and the outwardly directed grinding step may each be performed once or a plurality of times. If performed a plurality of times, the inwardly directed grinding step and the outwardly directed grinding step are alternately repeated. As described above, the circular thin plate portion 11d and the annular protrusion portion 11e (see FIG. 7) are formed in the workpiece 11 by grinding the back surface 13b of the wafer 13 to the predetermined target depth 11b (that is, until “YES” in S40).

In the present embodiment, the grinding of the workpiece 11 can be also performed without replacement of the grinding wheel 26. Further, with the grinding method according to the present embodiment, it is also possible to change the ring width of the annular protrusion portion 11e (see FIG. 7) or to grind another workpiece 11 having a different diameter from that of the above-described workpiece 11.

### Fifth Embodiment

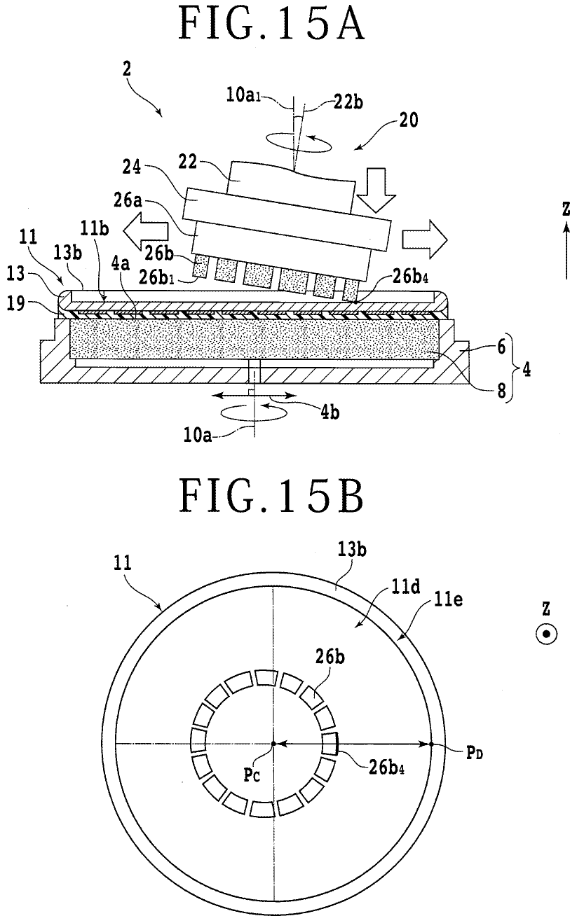

With reference to FIGS. 15A and 15B, a fifth embodiment will next be described. In the fifth embodiment, the rotary-shaft direction grinding step and radially directed grinding step S22 is performed after the holding step S10 as in the fourth embodiment (see FIG. 13). In the fifth embodiment, however, the back surface 13b of the wafer 13 is ground with the axis 22b of the spindle 22 (that is, the longitudinal direction of the spindle 22) arranged in non-parallel to the axis 10a of the rotary shaft 10 of the chuck table 4. The grinding feed of the grinding unit 20 and the reciprocation of the chuck table 4 are performed, for example, with the axis 22b of the spindle 22 kept inclined by a predetermined angle with respect to the axis 10a of the rotary shaft 10.

FIG. 15A is a partial cross-sectional side view illustrating the rotary-shaft direction grinding step and radially directed grinding step S22 in the fifth embodiment. It is to be noted that, in FIG. 15A, a straight line 10a₁ parallel to the axis 10a is drawn in a vicinity of the spindle 22 to clearly indicate the inclination of the spindle 22. In the rotary-shaft direction grinding step and radially directed grinding step S22, the chuck table 4 is reciprocated along the radial direction 4b in FIG. 15A while the grinding wheel 26 is fed downward for grinding, thereby grinding the back surface 13b of the wafer 13. It is to be noted that, in the rotary-shaft direction grinding step and radially directed grinding step S22, both the inwardly directed grinding step and the outwardly directed grinding step are alternately performed a plurality of times.

In particular, the back surface 13b of the wafer 13 is ground with, instead of the grinding surface 26b₂ of the grinding stones 26b, an arc-shaped outer peripheral edge 26b₄ of the bottom surface 26b₁ of each grinding stone 26b in the fifth embodiment. As illustrated in FIG. 15B, the arc-shaped outer peripheral edge 26b₄ of the bottom surface 26b₁ (see FIG. 15A) of each grinding stone 26b is thus reciprocated between a center P_{C} of the back surface 13b and a point P_{D} on an outer periphery of the circular thin plate portion 11d, the outer periphery corresponding to an inner peripheral edge of the annular protrusion portion 11e.

As the grinding proceeds, the center P_{C} of the back surface 13b gradually moves toward the front surface 13a. Similarly, the point P_{D} on the outer periphery of the circular thin plate portion 11d also gradually moves toward the front surface 13a as the grinding proceeds. The point P_{D} on the outer periphery is located on a boundary between the circular thin plate portion 11d and the annular protrusion portion 11e in a plane defined by the axis 22b of the spindle 22 and the axis 10a of the rotary shaft 10.

FIG. 15B is a top view illustrating the rotary-shaft direction grinding step and radially directed grinding step S22 in the fifth embodiment. In FIG. 15B, the arc-shaped outer peripheral edge 26b₄ of the bottom surface 26b₁ of one of the grinding stones 26b is illustrated by a thick curve. The arc-shaped outer peripheral edge 26b₄ corresponds, for example, to an outer peripheral portion of the bottom surface 26b₁ of the corresponding grinding stone 26b, but does not necessarily contribute in its entirety to the grinding. For example, only the region of a portion of the arc-shaped outer peripheral edge 26b₄ which is located at a lowermost end (that is, a processing point) may contribute to the grinding. The grinding wheel 26 is rotating during the grinding, so that the individual ones of the grinding stones 26b sequentially contribute to the grinding as time goes on.

The reciprocal movement of the outer peripheral edge 26b₄ is performed, for example, by reciprocating the chuck table 4 along the radial direction 4b in FIG. 15A. Taking into consideration any possible misregistration between the center of the holding surface 4a and the center P_{C} of the back surface 13b, the arc-shaped outer peripheral edge 26b₄ may be moved to an outer position which is opposite to the center P_{C} with respect to the point P_{D} on the outer periphery. Irrespective of whether the arc-shaped outer peripheral edge 26b₄ is moved to the point P_{D} on the outer periphery or is moved outward beyond the point P_{D}, the back surface 13b of the wafer 13 is ground until the predetermined target depth 11b is reached (that is, until “YES” in S40), so that the circular thin plate portion 11d and the annular protrusion portion 11e (see FIG. 7) are formed in the workpiece 11.

In the present embodiment, the grinding of the workpiece 11 can be also performed without replacement of the grinding wheel 26. Further, with the grinding method according to the present embodiment, it is also possible to change the ring width of the annular protrusion portion 11e (see FIG. 7) or to grind another workpiece 11 having a different diameter from that of the above-described workpiece 11. It is to be noted that the rotational speed of the chuck table 4, the rotational speed of the spindle 22, and/or the moving speed in the radial direction 4b of the chuck table 4 may be adjusted according to the position of the outer peripheral edge 26b₄ to make substantially uniform the volume of the workpiece 11 to be ground per unit time.

When the processing point is located at the center P_{C}, for example, the rotational speed of the chuck table 4, the rotational speed of the spindle 22, and the moving speed in the radial direction 4b of the chuck table 4 are set at 300 rpm, 4,000 rpm, and 1.0 mm/s, respectively. When the processing point is located at the point P_{D} on the outer periphery, on the other hand, the rotational speed of the chuck table 4, the rotational speed of the spindle 22, and the moving speed in the radial direction 4b of the chuck table 4 are set at 100 rpm, 6,000 rpm, and 0.1 mm/s, respectively.

If the processing point is located between the center P_{C} and the point P_{D} on the outer periphery, according to the position of the outer peripheral edge 26b₄, the rotational speed of the chuck table 4, the rotational speed of the spindle 22, and the moving speed in the radial direction 4b of the chuck table 4 may be changed in a range of 100 rpm or higher but 300 rpm or lower, in a range of 4,000 rpm or higher but 6,000 rpm or lower, and in a range of 0.1 mm/s or greater but 1.0 mm/s or smaller, respectively. This can make substantially constant the volume to be ground per unit time, and can thus provide the ground circular thin plate portion 11d with improved planarity compared with a case in which the rotational speeds of the chuck table 4 and the spindle 22 and the moving speed in the radial direction 4b of the chuck table 4 are set constant irrespective of the position of the outer peripheral edge 26b₄. In other words, total thickness variations (TTV) can be improved.

Moreover, the constructions, methods, and the like according to the above-described embodiments can be practiced with appropriate changes or modifications within the scope not departing from the object of the present invention. In the first to fourth embodiments (except for the fifth embodiment), for example, the wafer 13 can also be ground by using the chuck table 12 which is illustrated in FIG. 4 and which has the holding surface 12a of the double recessed shape. If the chuck table 12 having the holding surface 12a of the double recessed shape is used, however, at least one of the spindle 22 (the axis 22b) or the rotary shaft 10 (the axis 10a) of the chuck table 4 is inclined such that a processing region (specifically, a region of contact between the grinding stones 26b and the back surface 13b of the wafer 13) has an arc shape. Further, in the fifth embodiment, the rotary-shaft direction grinding step S20 and the radially directed grinding step S30 (S32, S34) may separately be performed as in the first embodiment (FIG. 1), the second embodiment (FIG. 8), and the third embodiment (FIG. 11).

The present invention is not limited to the details of the above described preferred embodiments. The scope of the invention is defined by the appended claims and all changes and modifications as fall within the equivalence of the scope of the claims are therefore to be embraced by the invention.

What is claimed is:

1. A workpiece grinding method of grinding a back surface of a workpiece having, on a front surface thereof, a device region and an outer peripheral surplus region surrounding the device region, to form a recessed portion in the back surface, thereby forming a circular thin plate portion and an annular protrusion portion surrounding the circular thin plate portion, the method comprising:
a holding step of holding the front surface of the workpiece with a holding surface of a chuck table that is rotatable about an axis of a rotary shaft;
a rotary-shaft direction grinding step of grinding the back surface of the workpiece by relatively moving a grinding unit and the chuck table toward each other along the axis of the rotary shaft of the chuck table, the grinding unit including a spindle having a distal end portion to which a grinding wheel is mounted, the grinding wheel including an annular base and a plurality of grinding stones that are arranged in an annular pattern on one surface of the base and that have outer peripheral surfaces defining a circle of a diameter not greater than a radius of the workpiece; and
a radially directed grinding step of grinding the back surface of the workpiece by relatively moving the grinding unit and the chuck table in a radial direction of the chuck table, the radial direction being orthogonal to the axis, wherein
the radially directed grinding step includes one of or both
an inwardly directed grinding step of grinding the workpiece while relatively moving the grinding unit and the chuck table from a position where a moving path of bottom surfaces of the grinding stones that is formed together with rotation of the spindle and the axis of the chuck table do not overlap each other to a position where the moving path and the axis of the chuck table overlap each other, and
an outwardly directed grinding step of grinding the workpiece while relatively moving the grinding unit and the chuck table from the position where the moving path and the axis overlap each other to the position where the moving path and the axis do not overlap each other.

2. The workpiece grinding method according to claim 1, wherein,
in the radially directed grinding step, the inwardly directed grinding step and the outwardly directed grinding step are alternately repeated to grind the workpiece.

3. The workpiece grinding method according to claim 1, wherein
the rotary-shaft direction grinding step and the radially directed grinding step are concurrently performed to grind the workpiece, and
the radially directed grinding step includes both the inwardly directed grinding step and the outwardly directed grinding step.

4. The workpiece grinding method according to claim 1, wherein,
in the holding step, the workpiece is held with the holding surface having a planarity of smaller than 10 μm in terms of roughness, and
in the rotary-shaft direction grinding step and the radially directed grinding step, the workpiece held with the holding surface having the planarity is ground.

5. The workpiece grinding method according to claim 4, wherein,
in the rotary-shaft direction grinding step and the radially directed grinding step, the workpiece is ground with an axis of the spindle of the grinding unit arranged in non-parallel with the axis of the chuck table.
